(19) United States
(12) Patent Application Publication
(10) Pub. No.: US 2015/0357373 A1
(43) Pub. Date: Dec. 10, 2015

(54) ARRAY SUBSTRATE AND MANUFACTURING METHOD THEREOF AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Lianjie QU, Beijing (CN); Jian GUO, Beijing (CN); Yiping DONG, Beijing (CN); Yu LIN, Beijing (CN)

(21) Appl. No.: 14/518,265

(22) Filed: Oct. 20, 2014

(30) Foreign Application Priority Data
Jun. 9, 2014 (CN) 201410253659.8

(51) Int. Cl. H01L 27/15; G02F 1/1335; H01L 33/28; H01L 33/06; H01L 33/08; G02F 1/1368; H01L 33/00

(52) U.S. Cl. CPC H01L 27/156; G02F 1/1368; G02F 1/1336; G02F 1/133514; H01L 33/0083; H01L 33/06; H01L 33/08; H01L 33/28; G02F 2001/133614

(57) ABSTRACT

The present invention provides an array substrate and a manufacturing method thereof and a display device, belonging to the field of display technology and solving the problems that the display quality is reduced and the normal watching is affected due to alignment shifting during alignment in an existing thin film transistor liquid crystal display. The array substrate of the present invention includes a plurality of sub-pixel units, wherein a plurality of light forming units corresponding to the sub-pixel units are arranged on a light-exiting surface of the array substrate, and each of the light forming unit is configured to form light of a color of the sub-pixel units corresponding thereto. When the array substrate of the present invention is applied to the display device, the display quality of the display device may be improved.

### FIELD OF THE INVENTION

The present invention relates to the field of display technology, and particularly relates to an array substrate and a manufacturing method thereof and a display device.

### BACKGROUND OF THE INVENTION

As a thin film transistor liquid crystal display (referred to as TFT-LCD) has the advantages of small size, low power consumption, no radiation, high resolution and the like, it plays a dominant role in the current display field and has been widely applied to various modern digital information equipments.

The TFT-LCD mainly includes two parts, namely a backlight module and a liquid crystal display panel. The backlight module is used for providing uniform white light for the liquid crystal display panel. The liquid crystal display panel includes an array substrate and a color film substrate, as well as a liquid crystal layer which is configured between the array substrate and a color filter substrate. In each sub-pixel unit of the array substrate, a corresponding pixel electrode works together with a common electrode (which may be positioned in the color filter substrate or the array substrate and is not shown in the figure) to control the rotation of liquid crystal molecules in the sub-pixel unit, so that the light transmittance at each sub-pixel unit is controlled to realize a display function; and color filters of corresponding colors are arranged on the color filter substrate in correspondence to different colors of sub-pixel units of the array substrate and are used for changing the light passing through each of the sub-pixel units into the light of corresponding color.

In the manufacture of a liquid crystal display panel, the color filter substrate and the array substrate need to be accurately aligned to form a cell, however, an alignment shifting may occur during the alignment of the color filter substrate and the array substrate; and when the alignment shifting is large, a color shift phenomenon may occur.

FIG. 1 shows a case in which a color filter substrate 2 and an array substrate 1 are properly aligned. The color filter substrate 2 includes red filters 21, green filters 22, blue filters 23 and a black matrix 24, the black matrix 24 is used for shading light passing through lead wires such as data lines 12 of the array substrate 1. When the color filter substrate 2 and the array substrate 1 are properly aligned, the light passing through different colors of sub-pixel units will pass through the color filters of the corresponding colors, so as to be changed into the light with proper colors.

FIG. 2 shows a case in which an alignment shifting occurs during alignment of the color filter substrate 2 and the array substrate 1, and the situation that the color filter substrate 2 shifts leftwards relative to the proper alignment position is taken as an example in the FIG. 2. It thus can be seen, when only red sub-pixel units are lightened (that is, light can only pass through red sub-pixel units), light (arrow in FIG. 2) which should irradiate onto the black matrix 24 to be shaded when the color filter substrate 2 and the array substrate 1 are properly aligned irradiates onto the edges of the green filters 22 (at this moment, the position of the black matrix 24 is changed so that the light cannot be shaded), and the light becomes green after being emitted out, resulting in that red is crossed with green. That is to say, the display device should display an all red picture, but the picture displayed by the display device is not a red picture but a non-red picture such as a pink picture or the like from the front or a certain inclined angle, namely, a color shift phenomenon occurs. Similarly, the sub-pixel units of another color also have the cross color problem, and because human eyes have the highest sensitivity to green, the influence on the watching effect is the greatest when red is crossed with green. That is to say, the color shift phenomenon produced by the alignment shifting during the alignment of the color filter substrate and the array substrate reduces the display quality of the display and affects normal watching of users.

### SUMMARY OF THE INVENTION

Technical problems to be solved by the present invention include, providing an array substrate and a manufacturing method thereof and a display device, which can eliminate the color shift phenomenon generated by alignment shifting during the alignment so as to improve the display quality of the display, in view of the problem that display quality is reduced and the normal watching is affected due to a color shift phenomenon generated by alignment shifting during the alignment in an existing thin film transistor liquid crystal display.

An embodiment of the present invention provides an array substrate including a plurality of sub-pixel units, wherein a plurality of light forming units corresponding to the sub-pixel units are arranged on a light-exiting surface of the array substrate, and each of the light forming units is configured to form light of a color of the sub-pixel unit which corresponds to the light forming unit.

The light forming units are arranged corresponding to the sub-pixel units of the array substrate of the present invention, and each of the light forming units may form light of a color of the corresponding sub-pixel unit, so that white light emitted by a backlight module already becomes light of corresponding colors at the respective sub-pixel units after passing through the array substrate. Thus, even if alignment shifting is generated during alignment of the array substrate and the color filter substrate, the light passing through a certain sub-pixel unit irradiates onto a color filter of another color (e.g. the light passing through a red sub-pixel unit irradiates onto a green filter), but it is known from the transmission principle of light that the rate that light (e.g. red light) of a certain color passes through a color filter (e.g. a green filter) having a color different from the color of the light is quite low and is nearly zero, and therefore, the light can hardly pass through the color filter of another color, thus avoiding cross color, that is, the color shift caused by alignment shifting during alignment of the array substrate and the color filter substrate can be effectively avoided.

An embodiment of the present invention further provides a display device comprising:

the above-mentioned array substrate; and

a color filter substrate aligned with the array substrate, wherein the color filter substrate includes a plurality of color filters of different colors corresponding to the sub-pixel units of the array substrate, and each of the color filters has the same color as the sub-pixel unit of the array substrate corresponding thereto.

An embodiment of the present invention further provides a manufacturing method of the above-mentioned array substrate, and the method includes:

Forming, on a light-exiting surface of the array substrate, light forming units corresponding to the sub-pixel units, wherein each of the light forming units is configured to form light of a color of the sub-pixel unit which correspond to the light forming unit.

### BRIEF DESCRIPTION OF THE DRAWINGS

FIG. 1 is a schematic sectional diagram of a structure when an existing array substrate and an existing color filter substrate are aligned properly;

FIG. 2 is a schematic sectional diagram of a structure when alignment shifting occurs during alignment of an existing array substrate and an existing color filter substrate;

FIG. 3 is a schematic sectional diagram of a structure of a liquid crystal display panel according to an embodiment of the present invention;

FIG. 4 is a schematic diagram showing principle that color shift is eliminated when alignment shifting occurs in a liquid crystal display panel according to an embodiment of the present invention.

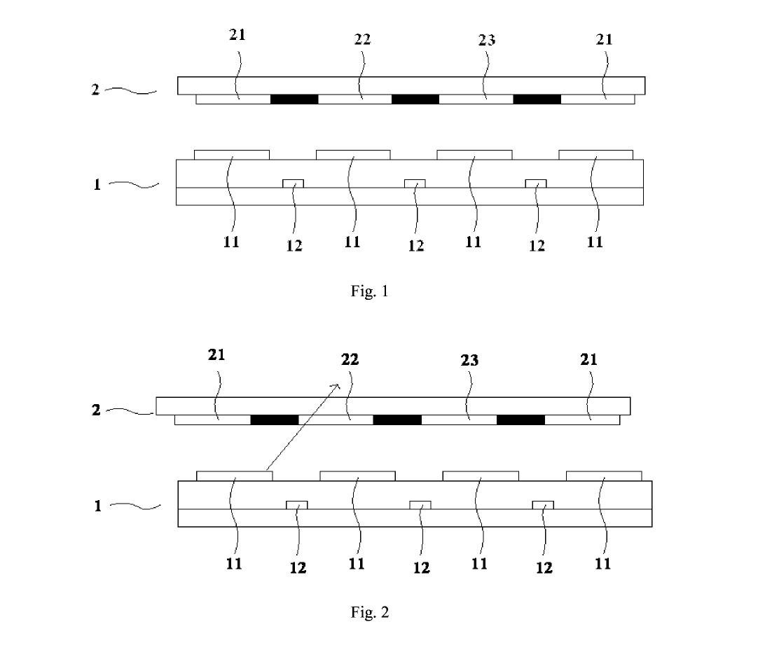

### DETAILED DESCRIPTION OF THE EMBODIMENTS

To make a person skilled in the art better understand the technical solution of the present invention, the present invention will be further described in detail below in conjunction with the accompanying drawings and specific embodiments. Apparently, the described embodiments are a part, but not all, of the embodiments of the present invention. All other embodiments obtained by the person skilled in the art based on the embodiments of the present invention without creative effort fall into the protection scope of the present invention.

### Embodiment 1

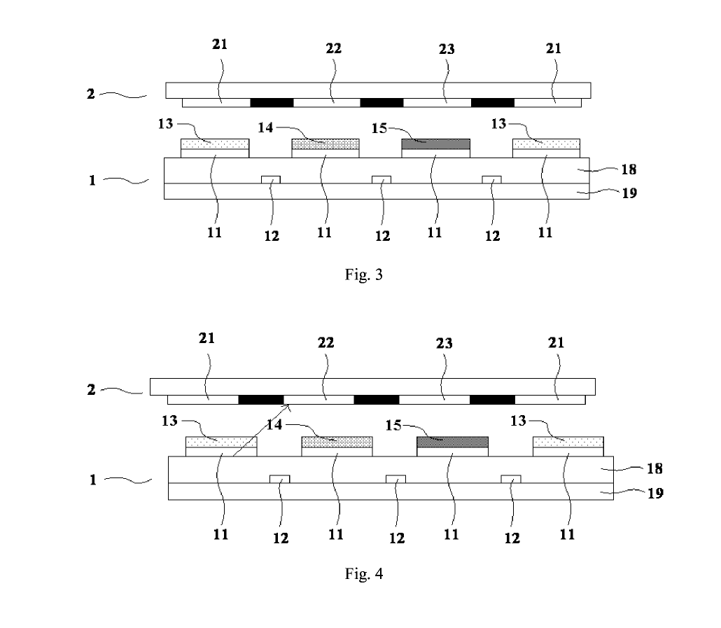

FIG. 3 is a schematic sectional diagram of a structure of a liquid crystal display panel according to an embodiment of the present invention; and FIG. 4 is a schematic diagram showing principle that color shift is eliminated when alignment shifting occurs in a liquid crystal display panel according to an embodiment of the present invention.

As shown in FIG. 3 and FIG. 4, this embodiment provides an array substrate 1 including a plurality of sub-pixel units (each sub-pixel unit has a respective color), wherein light forming units corresponding to the sub-pixel units and configured to form light in different colors are arranged on a light-exiting surface of the array substrate 1, that is to say, each of the light forming units is configured to form light of a color of the sub-pixel unit which correspond to the light forming unit.

The array substrate 1 and the color filter substrate 2 of this embodiment may form a liquid crystal display panel after being aligned and filled with liquid crystals, and the liquid crystal display panel may be applied in a display device. In the liquid crystal display panel, the sub-pixel units on the array substrate 1 and the color filters on the color filter substrate 2 are in one-to-one correspondence (namely each of the color filters has the same color as the sub-pixel unit corresponding thereto), and each sub-pixel unit and the color filter corresponding thereto form a sub-pixel.

In this embodiment, the situation that a backlight module of the display device emits white light and the color filter substrate 2 includes red filters 21, green filters 22 and blue filters 23 is taken as an example for illustration. Of course, it is also feasible that the color filter substrate 2 further includes color filters of other colors (such as yellow filters and cyan filters).

When a pure red picture is displayed, the red sub-pixel units in the array substrate 1 corresponding to the red filters 21 in the color filter substrate 2 is turned on, the white light emitted by the backlight module passes through the light forming units corresponding to the red sub-pixel units and provided on the light-exiting surface of the array substrate 1 and then becomes red light, and the red light may pass through the red filters 21 in the color filter substrate 2 at this moment, so that display of red is realized. In this process, if a small amount of red light irradiates onto the edges of color filters of another color adjacent to the red filters 1 in the color filter substrate 2 due to the alignment shifting generated during alignment of the array substrate 1 and the color filter substrate 2, the rate that the red light pass through the color filters having the color different from red is quite low and is nearly zero according to the transmission principle of light, so that the red light substantially can not be emitted out from those positions. Thus it can be seen that the light forming units corresponding to the sub-pixel units and configured to form light in different colors are arranged on the light-exiting surface of the array substrate 1 provided in this embodiment, so that the phenomenon of color shift due to the alignment shifting of the array substrate 1 and the color filter substrate 2 may be effectively avoided.

Preferably, each light forming unit in this embodiment includes a quantum dot layer which includes quantum dots capable of exciting light of a color of the sub-pixel unit corresponding to the light forming unit.

That is to say, each light forming unit may be a quantum dot layer using quantum dots as a main component (the quantum dot layer may further include a matrix material such as resin for forming a “layer structure”).

Here, the quantum dots are a quasi-zero-dimensional nano material and consist of a small quantity of atoms, and the sizes in three dimensions of each quantum dot are all below 100 nm. Due to the special sizes, after being irradiated with light, the quantum dots may absorb the energy of the light and then reemit the light at their own characteristic wavelengths (namely specific colors), so that the quantum dots may achieve a function of “forming light of specific colors”. Specifically, the emission spectra of the quantum dots may be controlled by changing the sizes and chemical components of the quantum dots. The quantum dots have the advantages of high photochemical stability and long fluorescence lifetime. Different quantum dots are adopted in the light forming units to form light in different colors in this embodiment, so that the array substrate of this embodiment has better performance and longer service life.

Of course, the above-mentioned light forming units configured to form light in different colors may also be color filters of different colors, namely the light forming units are not limited to the quantum dot layers.

Preferably, the light forming units in this embodiment include red light forming units (corresponding to the red sub-pixel units), green light forming units (corresponding to the green sub-pixel units) and blue light forming units (corresponding to the blue sub-pixel units). Each red light forming unit is a first quantum dot layer 13 comprising first quantum dots capable of exciting red light; each green light forming unit is a second quantum dot layer 14 comprising second quantum dots capable of exciting green light; and each blue light forming unit is a third quantum dot layer 15 comprising third quantum dots capable of exciting blue light. Of course, the light forming units may further include yellow light forming units and the like, and accordingly, each yellow light forming unit is a fourth quantum dot layer comprising fourth quantum dots capable of exciting yellow light.

Further preferably, the particle size of the first quantum dots is 18-20 nm; the particle size of the second quantum dots is 12-14 nm; and the particle size of the third quantum dots is 6-8 nm. Researches discover that the quantum dots with sizes within the above ranges may emit corresponding red, green and blue light, respectively.

Further preferably, the first quantum dots, the second quantum dots and the third quantum dots are any of CdSe (cadmium selenide), ZnS (zinc sulfide), CdS (cadmium sulfide) and CdTe (cadmium telluride), respectively.

As a preferred structure of this embodiment, the array substrate includes a substrate 19 and a gate layer (not shown in the figure, namely a layer on which gates and gate lines are provided), a gate insulating layer (not shown in the figure), a semiconductor layer (not shown in the figure, namely a layer on which an active layer is provided), a source and drain electrode layer (namely a layer on which sources, drains and data lines 12 are provided), a passivation layer 18 and a pixel electrode layer (namely a layer on which pixel electrodes 11 are provided) sequentially arranged on the substrate 19. Here, the light forming units, e.g. the first quantum dot layers 13, the second quantum dot layers 14 and the third quantum dot layers 15, are preferably arranged on the pixel electrode layer, and more specifically, the light forming units corresponding to the respective sub-pixel units may be directly positioned on the pixel electrodes 11 of the respective sub-pixel units (of course, may also exceed the pixel electrodes 11, as long as they do not exceed the sub-pixel units). In the array substrate 1, in most cases, the pixel electrode layer is positioned on the top layer, the pixel electrodes 11 in the pixel electrode layer need to be connected to the drains in the source and drain layer, and therefore, corresponding through-holes need to be formed in the passivation layer 18, the gate insulating layer and the like. If the first quantum dot layers 13, the second quantum dot layers 14 and the third quantum dot layers 15 (these layers are preferably arranged on the same layer) are arranged between the source and drain layer and the pixel electrode layer (or arranged below the pixel electrode layer), corresponding through-holes for connecting the pixel electrodes 11 to the drains also need to be formed in the first quantum dot layers 13, the second quantum dot layers 14 and the third quantum dot layers 15, so the process is relatively complicated. Therefore, the first quantum dot layers 13, the second quantum dot layers 14 and the third quantum dot layers 15 in this embodiment are preferably arranged on the pixel electrode layer, thus simplifying the process.

Of course, the first quantum dot layers 13, the second quantum dot layers 14 and the third quantum dot layers 15 in this embodiment are not limited to being arranged on the pixel electrode layer, as long as these layers are arranged on the light-exiting surface of the array substrate. Meanwhile, the structure of the array substrate of this embodiment is not limited to the above-mentioned structure of the array substrate, for example, the semiconductor layer and the gate insulating layer may also be positioned below the gate layer, that is, the thin film transistors in the array substrate may also have top-gate structures; for another example, common electrode may also be arranged in the array substrate (e.g. below the pixel electrodes, and an insulating layer is arranged between the common electrode and the pixel electrodes), and the like. In brief, the light forming units should be positioned above the pixel electrode layer.

Specifically, as shown in FIG. 3 and FIG. 4, the array substrate 1 and the color filter substrate 2 of this embodiment are aligned with each other and applied in a display device. Here, the first quantum dot layers 13 correspond to the red filters 21, the second quantum dot layers 14 correspond to the green filters 22, and the third quantum dot layers 15 correspond to the blue filters 23. As shown in FIG. 4, the alignment shifting occurs in the alignment of the array substrate 1 and the color filter substrate 2. When red is displayed, the sub-pixel units in the array substrate 1 corresponding to the red filters 21 of the color filter substrate 2 is lightened under the control of the pixel electrodes 11 corresponding thereto, the white light emitted from the backlight module passes through the first quantum dot layers 13 (comprising the first quantum dots) and then becomes red light, and the red light passes through the red filters 21 in the color filter substrate 2 and then is displayed. When the red light irradiates onto the edge of the green filters 22 adjacent to the red filters 21, the red light is shaded by the green filters 22, that is, the red light cannot pass through the green filters 22, thus eliminating the color shift phenomenon caused by cross color of red and green, and improving the display quality of the display device. Meanwhile, due to the presence of the first quantum dot layers 13 capable of exciting red light, the white light emitted by the backlight module passes through the first quantum dot layers 13 capable of exciting red light and then becomes red light, and the red light irradiates onto the red filter 21, which may further improve the chroma of the display device. Similarly, the principle when green or blue is displayed is the same as that when red is displayed, and therefore is not described in detail herein.

The light forming units corresponding to the sub-pixel units and configured to form light in different colors are arranged on the light-exiting surface of the array substrate 1 of this embodiment, and therefore the probability of color cast may be reduced.

### Embodiment 2

This embodiment provides a manufacturing method of an array substrate, the array substrate is the array substrate described in embodiment 1 and includes a plurality of sub-pixel units, and the manufacturing method of the array substrate includes steps of:

forming, on a light-exiting surface of the array substrate, light forming units corresponding to the sub-pixel units, wherein each of the light forming units is configured to form light of a color of the sub-pixel unit which correspond to the light forming unit.

Preferably, each light forming unit includes a quantum dot layer which includes quantum dots capable of exciting light of the color of the sub-pixel unit corresponding thereto;

and, the step of forming, on the light-exiting surface of the array substrate, light forming units corresponding to the sub-pixel units includes: forming, on the light-exiting surface of the array substrate, a pattern including the quantum dot layers corresponding to the sub-pixel units through a patterning process.

Further preferably, the light forming units include red light forming units, green light forming units and blue light forming units. Each red light forming unit is a first quantum dot layer comprising first quantum dots capable of exciting red light; each green light forming unit is a second quantum dot layer comprising second quantum dots capable of exciting green light; and each blue light forming unit is a third quantum dot layer comprising third quantum dots capable of exciting blue light. The manufacturing method of the array substrate specifically includes steps of:

forming a pattern including the first quantum dot layers on the light-exiting surface of the array substrate through a patterning process;

forming a pattern including the second quantum dot layers on a substrate subjected to the above-mentioned step through a patterning process; and forming a pattern including the third quantum dot layers on the substrate subjected to the above-mentioned steps through a patterning process.

Here, the first quantum dot layers, the second quantum dot layers and the third quantum dot layers correspond to the red filters, the green filters and the blue filters in the color filter substrate, respectively.

That is to say, when the array substrate includes multiple different colors of quantum dot layers, the quantum dot layers are preferably formed through different patterning processes, respectively. Of course, the sequence described in the above steps does not limit the forming sequence of the quantum dot layers, and the forming sequence of the quantum dot layers may be arbitrarily changed.

In the present invention, the patterning process is a process in which a part of a previously formed film layer is removed, and the remaining part of the film layer is formed as the required pattern Specifically, the patterning process may only include a photolithographic process, or include a photolithographic process and an etching step, and meanwhile may also include other processes such as printing and inkjet for forming a predetermined pattern; and the photolithographic process is a process including film forming, exposure, development and other processes for forming a pattern by using a photoresist, a mask, an exposure machine and the like. A corresponding patterning process may be selected according to a structure formed in the present invention.

### Embodiment 3

This embodiment provides a display device including the array substrate 1 described in Embodiment 1 and a color filter substrate aligned with the array substrate, the color filter substrate includes a plurality of color filters of different colors corresponding to the sub-pixel units of the array substrate, and each of the color filters has the same color as the sub-pixel unit of the array substrate corresponding thereto.

The display device provided in this embodiment may be any product or component with a display function such as a liquid crystal panel, electronic paper, a liquid crystal television, a liquid crystal display, a digital photo frame, a mobile phone or a tablet computer.

The display device of this embodiment includes the array substrate of Embodiment 1, and therefore, the display quality of the display device is higher.

It could be understood that, the foregoing implementations are merely exemplary implementations adopted for illustrating the principle of the present invention, but the protection scope of the present invention is not limited thereto. Various variations and improvements could be made by those of ordinary skill in the art without departing from the spirit and essence of the present invention, and these variations and improvements are regarded as the protection scope of the present invention.

1. An array substrate, comprising a plurality of sub-pixel units, wherein a plurality of light forming units corresponding to the sub-pixel units are arranged on a light-exiting surface of the array substrate, and each of the light forming units is configured to form light, of a color of the sub-pixel unit which corresponds to the light forming unit.

2. The array substrate according to claim 1, wherein each of the light forming units comprises:
a quantum dot layer which comprises quantum dots capable of exciting light of a color of the sub-pixel unit which corresponds to the light forming unit.

3. The array substrate according to claim 2, wherein the light forming units comprise:
red light forming units which correspond to red sub-pixel units, and the red light forming units are first quantum dot layers comprising first quantum dots capable of exciting red light;
green light forming units which correspond to green sub-pixel units, and the green light forming units are second quantum dot layers each comprising second quantum dots capable of exciting green light; and
blue light forming units which correspond to blue sub-pixel units, and the blue light forming units are third quantum dot layers each comprising third quantum dots capable of exciting blue light.

4. The array substrate according to claim 3, wherein
a particle size of the first quantum dots is 18-20 nm;
a particle size of the second quantum dots is 12-14 nm; and
a particle size of the third quantum dots is 6-8 nm.

5. The array substrate according to claim 3, wherein
materials forming the first quantum dots, the second quantum dots and the third quantum dots are any of CdSe, ZnS, CdS and CdTe.

6. The array substrate according to claim 1, wherein the array substrate comprises a pixel electrode layer, and the light forming units are arranged on the pixel electrode layer.

7. A display device, comprising:
an array substrate comprising a plurality of sub-pixel units, wherein a plurality of light forming units corresponding to the sub-pixel units are arranged on a light-exiting surface of the array substrate, and each of the light forming units is configured to form light of a color of the sub-pixel unit which corresponds to the light forming unit; and
a color filter substrate aligned with the array substrate, wherein the color filter substrate comprises a plurality of color filters of different colors corresponding to the sub-pixel units of the array substrate, and each of the color filters has the same color as the sub-pixel unit of the array substrate corresponding thereto.

8. The display device according to claim 7, wherein each of the light forming units is:
a quantum dot layer which comprises quantum dots capable of exciting light of a color of the sub-pixel unit which corresponds to the light forming unit.

9. A manufacturing method of an array substrate, wherein the array substrate comprises a plurality of sub-pixel units, and the manufacturing method comprise step of:
Forming, on a light-exiting surface of the array substrate, light forming units corresponding to the sub-pixel units, wherein each of the light forming units is configured to form light of a color of the sub-pixel units which corresponds to the light forming unit.

10. The manufacturing method of an array substrate according to claim 9, wherein each of the light forming units comprises:
a quantum dot layer which comprises quantum dots capable of exciting light of a color of the sub-pixel unit which corresponds to the light forming unit;
and, the step of forming, on a light-exiting surface of the array substrate, light forming units corresponding to the sub-pixel units comprises a step of:
forming, on the light-exiting surface of the array substrate, a pattern comprising the quantum dot layers corresponding to the sub-pixel units through a patterning process.
